(19) United States
(12) Patent Application Publication
(10) Pub. No.: US 2025/0192751 A1
(43) Pub. Date: Jun. 12, 2025

(54) CAPACITOR IN BULK ACOUSTIC WAVE DEVICE

(71) Applicant: Skyworks Global Pte. Ltd., Singapore (SG)

(72) Inventors: Kwang Jae Shin, Yongin-si (KR); Jae Hyung Lee, Seoul (KR); Yong Woo Jeon, Anseong (KR); Nobufumi Matsuo, Suita-Shi (JP); Hiroki Kamiguchi, Hirakata-Shi (JP); Hidekazu Nakanishi, Sakai-Shi (JP)

(21) Appl. No.: 18/965,131

(22) Filed: Dec. 2, 2024

Related U.S. Application Data
(60) Provisional application No. 63/609,012, filed on Dec. 12, 2023.
(60) Provisional application No. 63/609,010, filed on Dec. 12, 2023.

(51) Int. Cl. H03H 9/17

(52) U.S. Cl. CPC H03H 9/173

(57) ABSTRACT

A bulk acoustic wave device and a capacitor in a bulk acoustic wave device are disclosed. The bulk acoustic wave device can include a resonator, an interconnect structure, and a capacitor. The resonator includes a first electrode, a second electrode, a piezoelectric layer between the first and second electrodes, and a passivation layer over the second electrode such that the second electrode is positioned between the piezoelectric layer and the passivation layer. The interconnect structure includes a conductive layer. The capacitor includes the passivation layer positioned between the conductive layer and the first or second electrode in a first direction. The capacitor, the resonator, and the interconnect structure are positioned in a second direction different from the first direction.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/609,012, filed Dec. 12, 2023, titled “CAPACITOR IN BULK ACOUSTIC WAVE DEVICE,” and U.S. Provisional Patent Application No. 63/609,010, filed Dec. 12, 2023, titled “METHOD OF FORMING CAPACITOR IN BULK ACOUSTIC WAVE DEVICE,” are hereby incorporated by reference under 37 CFR 1.57 in their entirety.

### BACKGROUND

### Technical Field

Embodiments of this disclosure relate to acoustic wave devices, and in particular, to bulk acoustic wave devices with a bonding layer.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed. A bulk acoustic wave resonator can include a set of metal electrodes deposited on opposite surfaces of a piezoelectric material, generating a bulk acoustic wave within the volume of the piezoelectric material. The interaction between the electrodes and the piezoelectric material results in the formation and propagation of a bulk acoustic wave.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a bulk acoustic wave device including: a resonator including a first electrode, a second electrode, a piezoelectric layer between the first and second electrodes, and a passivation layer over the second electrode such that the second electrode is positioned between the piezoelectric layer and the passivation layer; an interconnect structure including a conductive layer; and a capacitor including the passivation layer positioned between the conductive layer and the first or second electrode in a first direction, the capacitor, the resonator, and the interconnect structure are positioned in a second direction different from the first direction.

In some embodiments, the techniques described herein relate to a bulk acoustic wave device wherein the capacitor is positioned between the resonator and the interconnect structure in the second direction.

In some embodiments, the techniques described herein relate to a bulk acoustic wave device wherein thicknesses of the second electrode in the resonator and the capacitor are the same.

In some embodiments, the techniques described herein relate to a bulk acoustic wave device wherein the first or second electrode includes ruthenium (Ru).

In some embodiments, the techniques described herein relate to a bulk acoustic wave device wherein the passivation layer in the capacitor is positioned between the conductive layer and the first electrode in the first direction, no portion of the piezoelectric layer overlaps an active region of the capacitor.

In some embodiments, the techniques described herein relate to a bulk acoustic wave device wherein the passivation layer in the capacitor is positioned between the conductive layer and the second electrode in the first direction, no portion of the first electrode overlaps an active region of the capacitor.

In some embodiments, the techniques described herein relate to a bulk acoustic wave device wherein the first or second electrode has a tapered edge at an edge region of the capacitor.

In some embodiments, the techniques described herein relate to a bulk acoustic wave device wherein the passivation layer has a plurality of dielectric layers.

In some embodiments, the techniques described herein relate to a bulk acoustic wave device wherein the plurality of dielectric layers include a silicon oxide layer and a bonding layer positioned between the second electrode and the silicon oxide layer.

In some embodiments, the techniques described herein relate to a bulk acoustic wave device wherein the passivation layer in the capacitor has a thickness in a range between 200 nanometers and 400 nanometers.

In some aspects, the techniques described herein relate to an acoustic wave device including: a bulk acoustic wave resonator including an electrode portion of a first conductive layer and a passivation portion of a dielectric layer, the electrode portion of the first conductive layer defining an electrode of the bulk acoustic wave resonator; an interconnect structure laterally positioned relative to the bulk acoustic wave resonator, the interconnect structure including an interconnect portion of a second conductive layer; and a capacitor laterally positioned relative to the bulk acoustic wave resonator and the interconnect structure, the capacitor including an insulator portion of the dielectric layer positioned vertically between conductor portions of the first and second conductive layers.

In some embodiments, the techniques described herein relate to an acoustic wave device wherein the capacitor is positioned laterally between the bulk acoustic wave resonator and the interconnect structure.

In some embodiments, the techniques described herein relate to an acoustic wave device wherein the first conductive layer includes ruthenium (Ru).

In some embodiments, the techniques described herein relate to an acoustic wave device wherein the bulk acoustic wave resonator further includes a third conductive layer defining a second electrode and a piezoelectric layer positioned between the electrode and the second electrode.

In some embodiments, the techniques described herein relate to an acoustic wave device wherein the passivation layer includes silicon oxide.

In some embodiments, the techniques described herein relate to an acoustic wave device wherein the dielectric layer in the capacitor has a thickness in a range between 200 nanometers and 400 nanometers.

In some aspects, the techniques described herein relate to a capacitor in a bulk acoustic wave device, the capacitor including: a first conductive layer having a material forming an electrode of a bulk acoustic wave resonator in the bulk acoustic wave device; an insulator over the first conductive layer having a material forming a passivation layer of the bulk acoustic wave resonator; and a second conductive layer over the insulator, the second conductive layer having a material forming a conductor of an interconnect structure in the bulk acoustic wave device.

In some embodiments, the techniques described herein relate to a capacitor wherein the material of the first conductive layer is ruthenium (Ru).

In some embodiments, the techniques described herein relate to a capacitor wherein the material of the insulator is silicon oxide.

In some embodiments, the techniques described herein relate to a capacitor wherein the material of the second conductive layer includes gold (Au), titanium (Ti), copper (Cu), aluminum (Al), or tungsten (W).

In some aspects, the techniques described herein relate to a method of forming a bulk acoustic wave device including: providing a first electrode, a second electrode, a piezoelectric layer between the first and second electrodes, and a passivation layer over the second electrode such that the second electrode is positioned between the piezoelectric layer and the passivation layer to form a resonator; forming an interconnect structure including a conductive layer; and providing the passivation layer positioned between the conductive layer and the first or second electrode in a first direction to form a capacitor, the capacitor, the resonator, and the interconnect structure are positioned in a second direction different from the first direction.

In some embodiments, the techniques described herein relate to a method wherein the passivation layer is provided after the first electrode, the second electrode, and the piezoelectric layer are provided, and before the interconnect structure is formed.

In some embodiments, the techniques described herein relate to a method wherein providing the first electrode includes etching at least a portion of the first electrode before providing the piezoelectric layer.

In some embodiments, the techniques described herein relate to a method wherein providing the second electrode includes etching at least a portion of the second electrode before providing the passivation layer.

In some embodiments, the techniques described herein relate to a method wherein the first or second electrode includes ruthenium (Ru).

In some embodiments, the techniques described herein relate to a method wherein the passivation layer in the capacitor is positioned between the conductive layer and the first electrode in the first direction, no portion of the piezoelectric layer overlaps an active region of the capacitor.

In some embodiments, the techniques described herein relate to a method wherein the passivation layer in the capacitor is positioned between the conductive layer and the second electrode in the first direction, no portion of the first electrode overlaps an active region of the capacitor.

In some embodiments, the techniques described herein relate to a method wherein providing the first or second electrode includes etching to taper an edge of the first or second electrode at an edge region of the capacitor.

In some embodiments, the techniques described herein relate to a method wherein the passivation layer has a plurality of dielectric layers including a silicon oxide layer and a bonding layer positioned between the second electrode and the silicon oxide layer.

In some embodiments, the techniques described herein relate to a method wherein the passivation layer in the capacitor has a thickness in a range between 200 nanometers and 400 nanometers.

In some aspects, the techniques described herein relate to a method of forming an acoustic wave device including: forming a first conductive layer having a first electrode portion and a first conductor portion; forming a dielectric layer having a passivation portion and an insulator portion; forming a second conductive layer having a second electrode portion; forming a piezoelectric layer at least partially between the first electrode portion and the second electrode portion; and forming a third conductive layer having an interconnect portion and a second conductor portion, the insulator portion of the dielectric layer positioned between the first conductor portion of the first conductive layer and the second conductor portion of the second conductive layer.

In some embodiments, the techniques described herein relate to a method wherein the first conductive layer is formed before forming the piezoelectric layer.

In some embodiments, the techniques described herein relate to a method wherein the first conductive layer is formed after forming the piezoelectric layer.

In some embodiments, the techniques described herein relate to a method wherein the insulator portion, the first conductor portion, and the second conductor portion together form at least a portion a capacitor, the piezoelectric layer, the first electrode portion, and the second electrode portion together form at least a portion of a resonator.

In some embodiments, the techniques described herein relate to a method wherein forming the piezoelectric layer includes removing a piezoelectric material from an area that overlaps an active region of the capacitor.

In some embodiments, the techniques described herein relate to a method wherein the passivation portion of the dielectric layer has a thickness in a range between 200 nanometers and 400 nanometers.

In some embodiments, the techniques described herein relate to a method wherein the dielectric layer includes silicon oxide.

In some aspects, the techniques described herein relate to a method of forming a capacitor in a bulk acoustic wave device including: forming a first conductive layer having a material forming an electrode of a bulk acoustic wave resonator in the bulk acoustic wave device; forming an insulator over the first conductive layer, the insulator having a material forming a passivation layer of the bulk acoustic wave resonator; and forming a second conductive layer over the insulator, the second conductive layer having a material forming a conductor of an interconnect structure in the bulk acoustic wave device.

In some embodiments, the techniques described herein relate to a method wherein the material of the first conductive layer includes ruthenium (Ru) and the material of the insulator is silicon oxide.

In some embodiments, the techniques described herein relate to a method wherein the material of the second conductive layer includes gold (Au), titanium (Ti), copper (Cu), aluminum (Al), or tungsten (W).

### BRIEF DESCRIPTION OF THE DRAWINGS

Embodiments of this disclosure will now be described, by way of non-limiting example, with reference to the accompanying drawings.

FIG. 1A is a schematic top plan view of a portion of a bulk acoustic wave (BAW) device according to an embodiment.

FIG. 1B is a schematic cross-sectional side view of a portion of the BAW device of FIG. 1A.

FIGS. 2A-2C are schematic cross-sectional side views at various steps of forming the BAW device of FIGS. 1A and 1B.

FIGS. 3A and 3B are graphs showing simulation results of three BAW devices each having a different capacitor.

FIG. 4A is a schematic top plan view of a portion of a BAW device according to an embodiment.

FIG. 4B is a schematic cross-sectional side view of a portion of the BAW device of FIG. 4A.

FIG. 4C is a schematic cross-sectional side view of another portion of the BAW device of FIG. 4A.

FIGS. 5A-5D are schematic cross-sectional side views at various steps of forming the BAW device of FIGS. 4A-4C.

FIG. 6A is a schematic top plan view of a portion of a BAW device according to an embodiment.

FIG. 6B is a schematic cross-sectional side view of a portion of the BAW device of FIG. 6A.

FIG. 6C is a schematic cross-sectional side view of another portion of the BAW device of FIG. 6A.

FIG. 7 is a schematic diagram of an example of an acoustic wave filter.

FIG. 8 is a schematic block diagram of a module that includes an antenna switch and duplexers that include one or more bulk acoustic wave devices.

FIG. 9A is a schematic block diagram of a module that includes a power amplifier, a radio frequency switch, and duplexers that include one or more bulk acoustic wave devices.

FIG. 9B is a schematic block diagram of a module that includes a low noise amplifier, a radio frequency switch, and acoustic wave filters that include one or more bulk acoustic wave devices.

FIG. 10 is a schematic block diagram of a module that includes a power amplifier, a radio frequency switch, a duplexer that includes one or more bulk acoustic wave devices.

FIG. 11A is a schematic block diagram of a wireless communication device that includes filters that include one or more bulk acoustic wave devices.

FIG. 11B is a schematic block diagram of another wireless communication device that includes filters that include one or more bulk acoustic wave devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with bulk acoustic wave (BAW) devices. A film acoustic wave resonator (FBAR) and a BAW solidly mounted resonator (SMR) are examples of BAW devices. A bandwidth of a filter is defined as the range of frequencies over which the device can effectively filter or transmit signals. A larger effective electromechanical coupling coefficient or coupling factor (Kₜ²) can contribute to providing a wider bandwidth in a BAW device. However, when a relatively large Kₜ² resonator is used in the BAW device, the skirt performance and the insertion loss can be degraded.

A capacitor can provide additional capacitance in the BAW device's circuit. An on-die capacitor is an example of the capacitor. Capacitors can be used for various purposes in electronic circuits, such as tuning the resonant frequency or providing impedance matching. The capacitors can be strategically coupled with BAW resonators to achieve specific electrical characteristics. For example, the on-die capacitor can be used in a BAW device to improve the skirt performance and the insertion loss. Certain types of a resonator-type capacitor (e.g., a capacitor that uses a piezoelectric material of a resonator as its insulating material) that has a relatively high quality factor (Q) can be used in a BAW device to mitigate the degradation of the skirt performance and the insertion loss. However, since the quality factor Q at the original resonance frequency of a resonator-type capacitor can be significantly high, the resonance frequency can interfere with another filter (such as an adjacent filter), the resonator-type capacitor application can be limited. Also, a size (e.g., thickness) of the resonator-type capacitor can be relatively large.

Various embodiments disclosed herein relate to bulk acoustic wave (BAW) devices and capacitors integrated with or in BAW devices. Various embodiments disclosed herein also relate to methods of forming the BAW devices and the capacitors. A BAW device according to some embodiments can include a resonator, an interconnect structure, and a capacitor. The resonator can include a first electrode, a second electrode, a piezoelectric layer between the first and second electrodes, and a passivation layer over the second electrode such that the second electrode is positioned between the piezoelectric layer and the passivation layer. The interconnect structure can include a conductive layer. The capacitor can include the passivation layer that is positioned between the conductive layer and the first or second electrode in a first direction. The capacitor is positioned between the resonator and the interconnect structure in a second direction different from the first direction. Capacitors according to embodiments disclosed herein can provide a relatively high quality factor (Q). The capacitors according to some embodiments utilize the passivation layer as the insulator of the capacitor. Therefore, a size (e.g., thickness) of the capacitor can be relatively small. For example, the thickness of the capacitor can be smaller than a resonator-type capacitor that uses a piezoelectric material as the insulator. The capacitors disclosed herein can be formed using the processes used for forming a resonator and an interconnect. Thus, no additional process step may be needed to form the capacitors, which enables the manufacturing cost and the manufacturing time to be minimized.

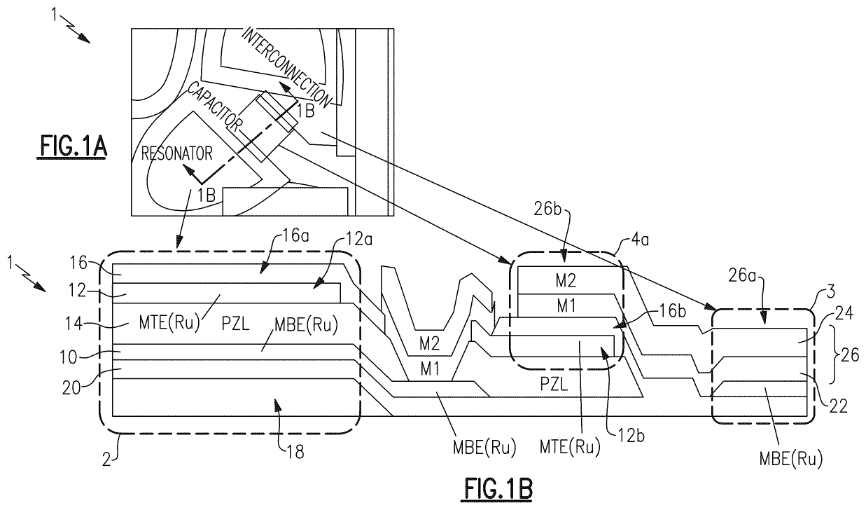

FIG. 1A is a schematic top plan view of a portion of a bulk acoustic wave (BAW) device 1 according to an embodiment. FIG. 1B is a schematic cross-sectional side view of a portion of the BAW device 1 shown in FIG. 1A. In some applications, the BAW device 1 can be an acoustic wave filter. The BAW device 1 can include a resonator 2, an interconnect structure 3, and a capacitor 4a. The resonator 2 can include a first electrode 10, a second electrode 12, a piezoelectric layer (or PZL) 14 between the first and second electrodes (or MBE and MTE) 10, 12, and a first passivation layer 16 over the second electrode 12 such that the second electrode 12 is positioned between the piezoelectric layer 14 and the first passivation layer 16. The resonator 2 can also include a cavity 18 (e.g., an air cavity) and a second passivation layer 20. The resonator 2 illustrated in FIG. 1A is a film bulk acoustic wave resonator (FBAR). The resonator 2, in some embodiments, can be a BAW solidly mounted resonator (SMR). The interconnect structure 3 can include one or more conductive layers such as a first conductive layer (or M1) 22 and a second conductive layer (or M2) 24 that can define an interconnect 26. The capacitor 4a can include the first passivation layer 16 that is positioned between at least one of the first and second conductive layers 22, 24 and the second electrode 12 in a first direction (e.g., in a vertical direction). The capacitor 4a can be positioned between the resonator 2 and the interconnect structure 3 in a second direction (e.g., a lateral or horizontal direction) different from the first direction.

The first electrode 10 can have a relatively high acoustic impedance. The first electrode 10 can include molybdenum (Mo), tungsten (W), ruthenium (Ru), chromium (Cr), iridium (Ir), platinum (Pt), Ir/Pt, or any suitable alloy and/or combination thereof. The second electrode 12 can have a relatively high acoustic impedance. The second electrode 12 can include Mo, W, Ru, Cr, Ir, Pt, Ir/Pt, or any suitable alloy and/or combination thereof. The second electrode 12 can be formed of the same material as the first electrode 10 in certain instances. The thickness of the first electrode 10 can be approximately the same as the thickness of the second electrode 12 in a main acoustically active region of the resonator 2.

The piezoelectric layer 14 is at least partially positioned between the first electrode 10 and the second electrode 12. The piezoelectric layer 14 can include aluminum nitride, zinc oxide, or any other suitable piezoelectric material. The piezoelectric layer 14 can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain instances, the piezoelectric layer 14 can be an aluminum nitride layer doped with scandium. Doping the piezoelectric layer 14 can adjust resonant frequency. Doping the piezoelectric layer 14 can increase the coupling coefficient k² of the resonator 2. Doping to increase the coupling coefficient k² can be advantageous at higher frequencies where the coupling coefficient k² can be degraded.

The first passivation layer 16 can include a material that functions as a frequency trimming layer. Therefore, the first passivation layer 16 can be referred to as a passivation and trimming layer, as the first passivation layer 16 can be used for both passivation and frequency trimming or frequency adjustment. The first passivation layer 16 can be a dielectric layer. In some embodiments, the first passivation layer 16 can be a silicon oxycarbide layer, a silicon dioxide layer, or any other suitable passivation layer. The second passivation layer 20 can be a dielectric layer. In some embodiments, the second passivation layer 20 can be a silicon oxycarbide layer, a silicon dioxide layer, or any other suitable passivation layer.

In some embodiments, the BAW device 1 can include a bonding layer (not shown) between the second electrode 12 and the first passivation layer 16. For example, the bonding layer can include a piezoelectric material, such as a material of the piezoelectric layer 14.

The first conductive layer 22 and the second conductive layer 24 can include a material suitable for interconnecting components in the BAW device 1 or a component in the BAW device 1 with an external component. The first conductive layer 22 and/or the second conductive layer 24 can be highly conductive. For example, the first conductive layer 22 and/or the second conductive layer 24 can be more electrically conductive than the first electrode 10 and/or the second electrode 12. In some embodiments, the first conductive layer 22 and/or the second conductive layer 24 can include gold (Au), titanium (Ti), copper (Cu), aluminum (Al), or tungsten (W).

A capacitor can include conductors and an insulator positioned between the conductors. In the capacitor 4a, the second electrode 12 of the resonator 2 and the interconnect 26 of the interconnect structure 3 can define the conductors and the first passivation layer 16 can define the insulator. A portion of the second electrode 12 in the resonator 2 can be referred to as an electrode portion or a resonator portion 12a and a portion of the second electrode 12 in the capacitor 4a can be referred to as a conductor portion or a capacitor portion 12b. A portion of the interconnect 26 in the interconnect structure 3 can be referred to as a interconnect portion 26a and a portion of the interconnect 26 in the capacitor 4a can be referred to as a conductor portion or a capacitor portion 26b. A portion of the first passivation layer 16 in the resonator 2 can be referred to as a passivation portion or a resonator portion 16a and a portion of the first passivation layer 16 in the capacitor 4a can be referred to as an insulator portion or a capacitor portion 16b. An area in the capacitor 4a where the capacitor portions 12b, 26b, 16b overlap can define an active region of the capacitor 4a. In some embodiments, no portion of the first electrode overlaps the active region of the capacitor 4a.

When an edge of the second electrode 12 has a steep or near right angle at an edge region of the capacitor 4a, energy can be confined and the interconnect 26 may be damaged (e.g., delaminated from the first passivation layer 16) especially in case of a relatively high voltage application. Therefore, the edge of the second electrode 12 at the edge region of the capacitor 4a can be tapered or sloped, in some embodiments.

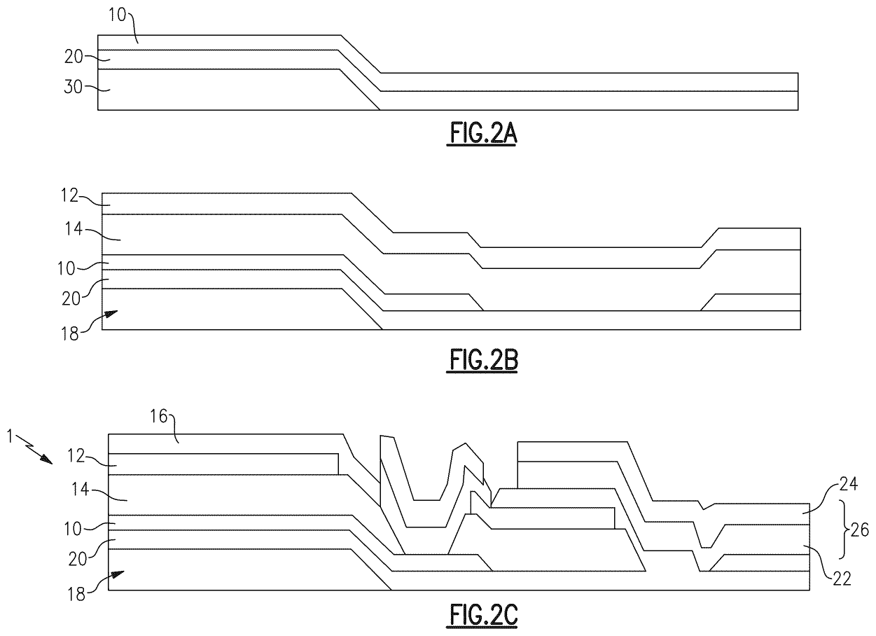

A method of forming the capacitor 4a can include processes of forming the resonator 2 and the interconnect structure 3. An example method of forming the BAW device 1 will be described with respect to FIGS. 2A-2C below. In some embodiments, no additional process may be needed other than the processes of forming the resonator 2 and the interconnect structure 3 to form the capacitor 4a. This can be beneficial because introducing one or more additional processes can increase manufacturing costs, increase manufacturing time, and/or complicate the forming method.

In some embodiments, thicknesses of the second electrode 12 in the resonator 2 and in the capacitor 4a can be the same or generally similar. In some embodiments, thicknesses of the interconnect 26 (e.g., the first conductive layer 22 and/or the second conductive layer 24) in the interconnect structure 3 and in the capacitor 4a can be the same or generally similar. In some embodiments, thicknesses of the first passivation layer 12 in the resonator 2 and in the capacitor 4a can be the same or generally similar. These likenesses in the thicknesses of layers in different portions of the BAW device 1 can be structural indications of utilizing the processes of forming the resonator 2 and the interconnect structure 3 in the method of forming the capacitor 4a.

In some other embodiments, the thicknesses of layers in different portions of the BAW device 1 can be different. For example, the thicknesses of the second electrode 12, the interconnect 26, and the first passivation layer 16 in the capacitor 4a can be adjusted to form the capacitor 4a with a desired capacitance. In some embodiments, a thickness of the second electrode 12 can be in a range between 200 nanometers and 1100 nanometers, 200 nanometers and 750 nanometers, 200 nanometers and 500 nanometers, 300 nanometers and 1100 nanometers, 500 nanometers and 1100 nanometers, or 750 nanometers and 1100 nanometers. In some embodiments, a thickness of the first passivation layer 16 can be in a range between 200 nanometers and 400 nanometers, 200 nanometers and 300 nanometers, or 300 nanometers and 400 nanometers. In some embodiments, a thickness of the bonding layer between the second electrode 12 and the first passivation layer 16 can be in a range between 2 nanometers and 20 nanometers, 2 nanometers and 10 nanometers, or 5 nanometers and 15 nanometers.

The resonator 2, the interconnect structure 3, and the capacitor 4a can be disposed on a support structure. The support structure can have a multi-layer structure. For example, the support structure can include a support substrate (e.g., a semiconductor substrate such as a silicon substrate), a trap rich layer, a passivation layer, or one or more intermediate layers therebetween.

FIGS. 2A-2C are schematic cross-sectional side views at various steps of forming the BAW device 1. FIG. 2A shows a sacrificial layer 30, the second passivation layer 20, and the first electrode 10. The sacrificial layer 30 can be deposited on a support structure and at least a portion of the sacrificial layer 30 can be removed and/or patterned to define a desired shape (e.g., a shape of a later formed cavity). The second passivation layer 20 and the first electrode 10 can be provided (e.g., deposited) over the sacrificial layer 30. The second passivation layer 20 can, for example, protect the first electrode 10 during a sacrificial layer removal process for removing the sacrificial layer 30.

FIG. 2B shows the piezoelectric layer 14 and the second electrode 12 provided (e.g., deposited) over the second passivation layer 20 and the first electrode 10. The sacrificial layer 30 can be removed to define the cavity 18. Between FIGS. 2A and 2B, at least portions of the second passivation layer 20 and the first electrode 10 can be removed (e.g., etched). The removal process(es) can include, lift-off, and/or ashing, in some embodiments. In some embodiments, a portion of the piezoelectric layer 14 can be in contact with the second passivation layer 20.

FIG. 2C shows the first passivation layer 16 and the interconnect 26 including the first and second conductive layers 22, 24 provided (e.g., deposited) over the piezoelectric layer 14, the second electrode 12, the second passivation layer 20, and the first electrode 10. Between FIGS. 2B and 2C, at least portions of the piezoelectric layer 14 and the second electrode 12 can be removed (e.g., etched). An edge of the second electrode 12 is shown to have a steep or near right angle. However, an additional process, such as an additional etching process, can provide a tapered or sloped edge for one or more edges of the second electrode 12. In such embodiments, it can be beneficial to maintain the steep or near right angle for the edge of the second electrode in the resonator 2 as the tapered or sloped edge can degrade the Q value of the resonator 2. Between FIGS. 2B and 2C, at least portions of the passivation layer 16 can be removed (e.g., etched). For example, the portions of the passivation layer 16 can be removed prior to providing the first and second conductive layers 22, 24. In some embodiments, providing the first and second conductive layers 22, 24 can include providing conductive material layers and removing at least portions of the conductive material layers to pattern the first and second conductive layers 22, 24. The removal processes can include photolithography, lift-off, and/or ashing, in some embodiments. In some embodiments, portions of the first conductive layer 22 can be in contact with the first passivation layer 16, the first electrode 10, and/or the piezoelectric layer 14.

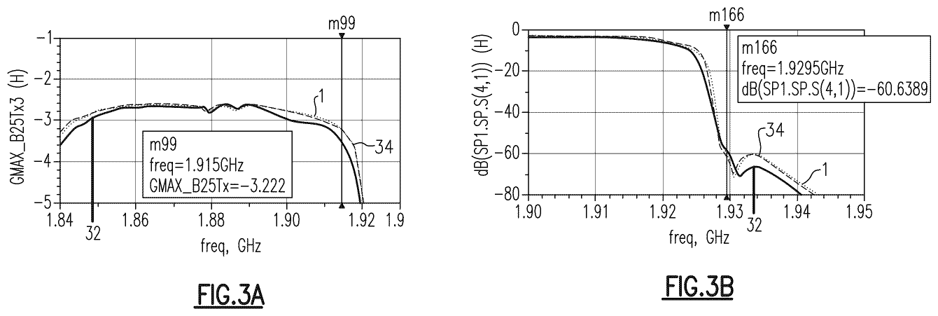

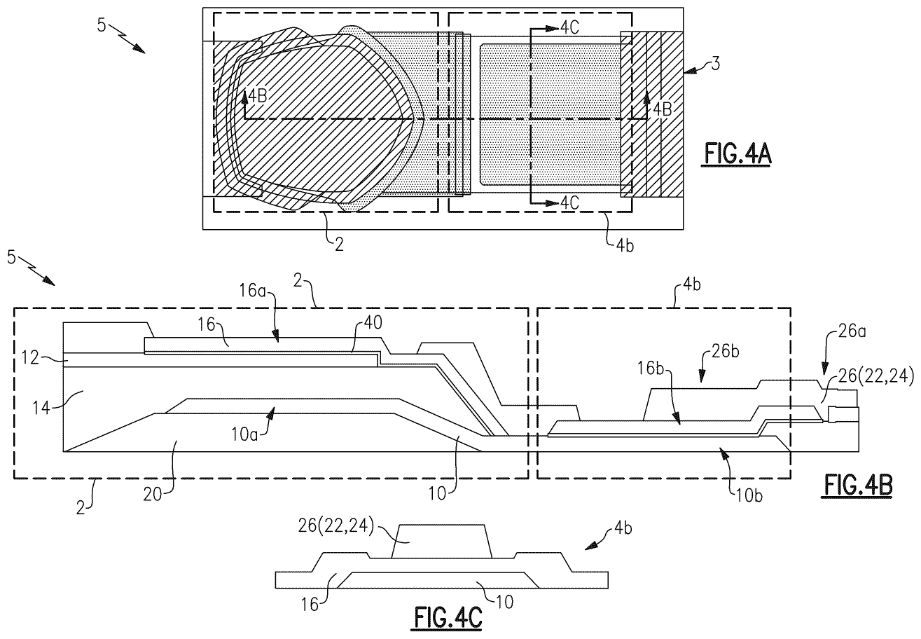

FIGS. 3A and 3B are graphs showing simulation results of three bulk acoustic wave (BAW) devices having different capacitors. The graph of FIG. 3A shows frequency in the x-axis and conductance in the y-axis. The graph of FIG. 3B shows frequency in the x-axis and insertion loss in the y-axis. The three BAW devices include the BAW device 1 having the capacitor 4a, a BAW device 32 having a resonator-type capacitor, and a BAW device 34 having a resonator type capacitor with a raised frame structure. The simulation results indicate that the capacitor 4a can improve the skirt performance and the insertion loss as compared to the BAW device 32. The capacitor 4a can improve the performance of the BAW device 1 and reduce the size (e.g., thickness) as compared to a similar BAW device that includes a resonator-type capacitor. Capacitors shown in FIGS. 4A-6C can provide like benefits as those of the capacitor 4a.

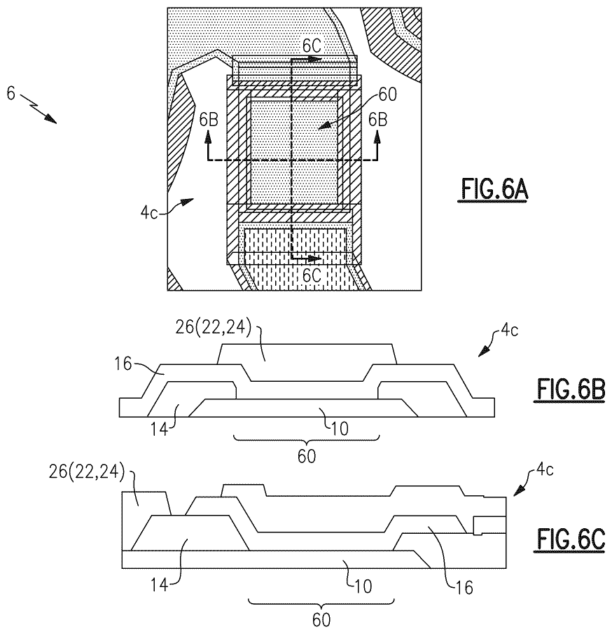

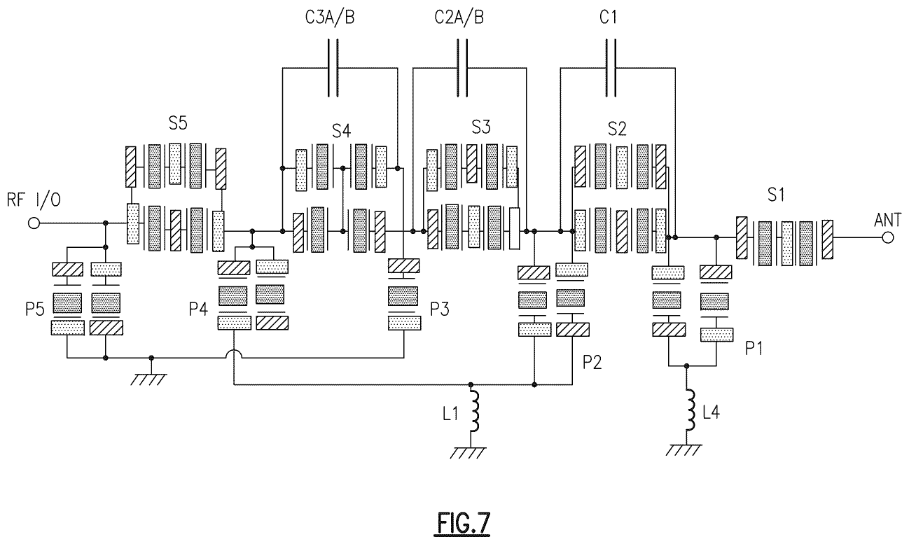

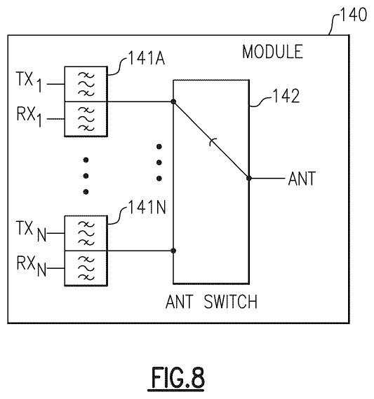

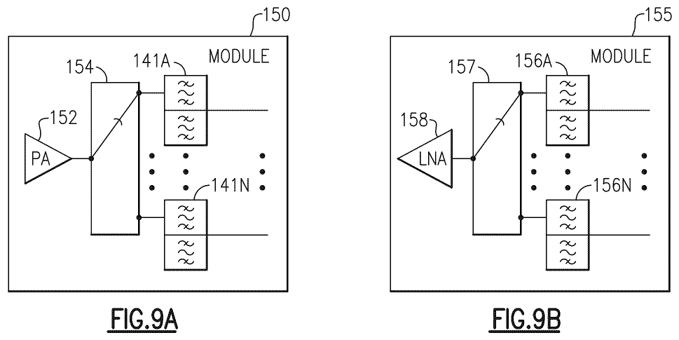

The capacitor 4a shown in FIGS. 1A and 1B utilizes the second electrode 12 of the resonator 2 and the interconnect 26 of the interconnect structure 3 as the conductors and the first passivation layer 12 as the insulator. In some other embodiments, such as those shown in FIGS. 4A-4C and 6A-6C, the first electrode 12 of the resonator 2 can define one of the conductors.

FIG. 4A is a schematic top plan view of a portion of a bulk acoustic wave (BAW) device 5 according to an embodiment. FIG. 4B is a schematic cross-sectional side view of a portion of the BAW device 5 shown in FIG. 4A. FIG. 4C is a schematic cross-sectional side view of another portion of the BAW device 5 shown in FIG. 4A.

The BAW device 5 can include a resonator 2, an interconnect structure 3, and a capacitor 4b. The resonator 2 can include a first electrode 10, a second electrode 12, a piezoelectric layer 14 between the first and second electrodes 10, 12, and a first passivation layer 16 over the second electrode 12 such that the second electrode 12 is positioned between the piezoelectric layer 14 and the first passivation layer 16. The resonator 2 can also include a cavity 18 (e.g., an air cavity) and a second passivation layer 20. The interconnect structure 3 can include one or more conductive layers such as a first conductive layer 22 and a second conductive layer 24 that define an interconnect 26. The capacitor 4b can include the first passivation layer 16 that is positioned between at least one of the first and second conductive layers 22, 24 and the first electrode 10 in a first direction (e.g., in a vertical direction). The capacitor 4b can be positioned between the resonator 2 and the interconnect structure 3 in a second direction (e.g., a lateral or horizontal direction) different from the first direction. Unless otherwise noted, the components of the BAW device 5 shown in FIGS. 4A-4C can be structurally and/or functionally the same as or generally similar to like components disclosed herein, such as the components of the BAW device 1 of FIGS. 1A and 1B.

In some embodiments, as shown in FIGS. 4B and 4C, the BAW device 5 can include a bonding layer 40 below the first passivation layer 16. For example, the bonding layer 40 can be provided between the second electrode 12 and the first passivation layer 16 in the resonator 2 and/or between the first electrode 10 and the first passivation layer 16 in the capacitor 4b. The bonding layer 40 can include a piezoelectric material, such as a material of the piezoelectric layer 14. The bonding layer 40 can be relatively thin. For example, the thickness of the bonding layer 40 can be in a range between 1% and 10% of the thickness of the first passivation layer 16. In some embodiments, the first passivation layer 16 and the bonding layer 40 can together form a multi-layer passivation structure.

In the capacitor 4b, the first electrode 10 of the resonator 2 and the interconnect 26 of the interconnect structure 3 can define the conductors and the first passivation layer 16 can define the insulator. A portion of the first electrode 10 in the resonator 2 can be referred to as an electrode portion or a resonator portion 10a and a portion of the first electrode 10 in the capacitor 4b can be referred to as a conductor portion or a capacitor portion 10b. A portion of the interconnect 26 in the interconnect structure 3 can be referred to as an interconnect portion 26a and a portion of the interconnect 26 in the capacitor 4b can be referred to as a conductor portion or a capacitor portion 26b. A portion of the first passivation layer 16 in the resonator 2 can be referred to as a passivation portion or a resonator portion 16a and a portion of the first passivation layer 16 in the capacitor 4b can be referred to as an insulator portion or a capacitor portion 16b. An area in the capacitor 4b where the capacitor portions 10b, 26b, 16b overlap can define an active region of the capacitor 4b. In some embodiments, no portion of the piezoelectric layer 14 may be positioned in the active region of the capacitor 4b.

An edge of the first electrode 10 used in the resonator 2 can be tapered or sloped. Therefore, when the first electrode 10 is used in the capacitor as the conductor, no additional process is needed to make the edge of the first electrode 10 at an edge region of the capacitor 4b tapered or sloped.

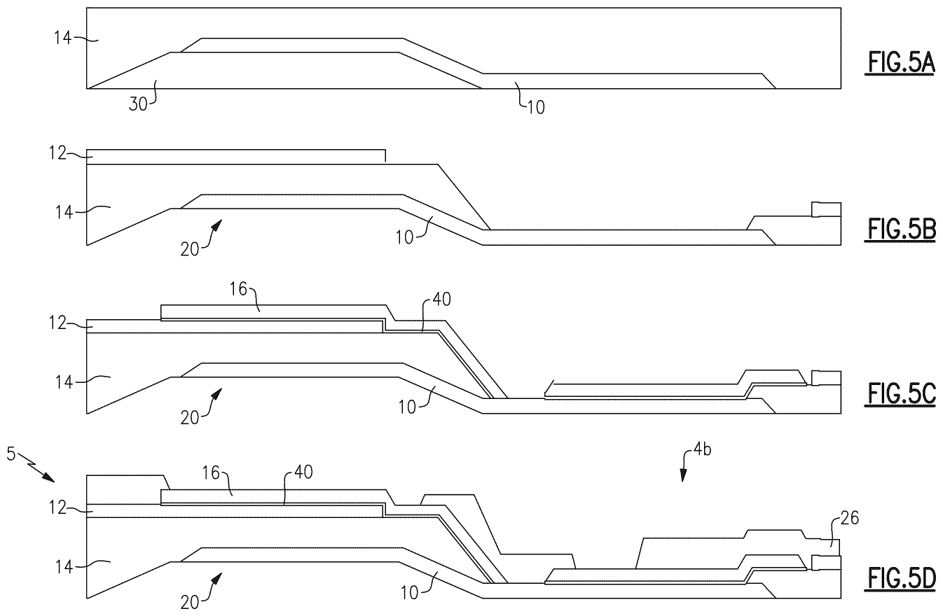

A method of forming the capacitor 4b can include processes of forming the resonator 2 and the interconnect structure 3. An example method of forming the BAW device 5 will be described with respect to FIGS. 5A-5D below. In some embodiments, no additional process may be needed other than the processes of forming the resonator 2 and the interconnect structure 3 to form the capacitor 4b. This can be beneficial because introducing one or more additional processes can increase manufacturing costs, increase manufacturing time, and/or complicate the forming method.

In some embodiments, thicknesses of the first electrode 10 in the resonator 2 and in the capacitor 4b can be the same or generally similar. In some embodiments, thicknesses of the interconnect 26 (e.g., the first conductive layer 22 and/or the second conductive layer 24) in the interconnect structure 3 and in the capacitor 4b can be the same or generally similar. In some embodiments, thicknesses of the first passivation layer 16 in the resonator 2 and in the capacitor 4a can be the same or generally similar. These likenesses in the thicknesses of layers in different portions of the BAW device 1 can be structural indications of utilizing the processes of forming the resonator 2 and the interconnect structure 3 in the method of forming the capacitor 4a.

In some other embodiments, the thicknesses of layers in different portions of the BAW device 5 can be different. For example, the thicknesses of the second electrode 12, the interconnect 26, and the first passivation layer 12 in the capacitor 4b can be adjusted to form the capacitor 4b with a desired capacitance. In some embodiments, a thickness of the first electrode 12 can be in a range between 50 nanometers and 550 nanometers, 50 nanometers and 450 nanometers, 50 nanometers and 300 nanometers, 100 nanometers and 550 nanometers, 200 nanometers and 550 nanometers, or 100 nanometers and 450 nanometers. In some embodiments, a thickness of the first passivation layer 16 can be in a range between 200 nanometers and 400 nanometers, 200 nanometers and 300 nanometers, or 300 nanometers and 400 nanometers. In some embodiments, a thickness of the bonding layer 40 between the first electrode 10 and the first passivation layer 16 can be in a range between 2 nanometers and 20 nanometers, 2 nanometers and 10 nanometers, or 5 nanometers and 15 nanometers.

FIGS. 5A-5D are schematic cross-sectional side views at various steps of forming the BAW device 5. FIG. 5A shows a sacrificial layer 30, the first electrode 10, and the piezoelectric layer 14. The sacrificial layer 30 can be deposited on a support structure and at least a portion of the sacrificial layer 30 can be removed to define a desired shape (e.g., a shape of a later formed cavity). In some embodiments, a passivation layer can be provided over the sacrificial layer 30 to, for example, protect the first electrode 10 during a sacrificial layer removal process for removing the sacrificial layer 30. In some embodiments, a material of the first electrode 10 can be provided (e.g., deposited) on the sacrificial layer 30 and the support structure, and portions of the material can be removed (e.g., etched) to pattern the first electrode 10.

FIG. 5B shows the second electrode 12 provided (e.g., deposited) over the piezoelectric layer and the first electrode. The sacrificial layer 30 can be removed to define the cavity 18. Portions of the piezoelectric layer 14 can be removed (e.g., etched) at least from a region for which the capacitor 4b will be formed. In some embodiments, a material of the second electrode 12 can be provided (e.g., deposited) on the piezoelectric layer 14, and portions of the material can be removed (e.g., etched) to pattern the second electrode 12.

FIG. 5C shows the bonding layer 40 and the first passivation layer 16 over the first electrode 10 and the piezoelectric layer 14. The bonding layer 40 and the first passivation layer 16 can be provided by way of, for example, deposition. In some embodiments, a material of the first passivation layer 16 can be provided (e.g., deposited) on the bonding layer 40, and portions of the material can be removed (e.g., etched) to pattern the passivation layer 16.

FIG. 5D shows the interconnect 26 provided (e.g., deposited) over the structure of FIG. 5C. In some embodiments, providing the interconnect 26 can include providing one or more conductive material layers and removing at least portions of the conductive material layers to pattern the interconnect 26. The removal processes can include photolithography, lift-off, and/or ashing, in some embodiments.

In the removal process of removing the portions of the piezoelectric layer 14 in FIG. 5B, less portions of the piezoelectric layer 14 can be removed and more portions of the piezoelectric layer 14 may be maintained. FIGS. 6A and 6B show a capacitor 4c with less portions of the piezoelectric layer 14 removed relative to the capacitor 4b shown in FIGS. 4A-4C, and 5D.

FIG. 6A is a schematic top plan view of a portion of a bulk acoustic wave (BAW) device 6 according to an embodiment. FIG. 6B is a schematic cross-sectional side view of a portion of the BAW device 6 shown in FIG. 6A. FIG. 6C is a schematic cross-sectional side view of another portion of the BAW device 6 shown in FIG. 6A.

The BAW device 6 can include a resonator 2, an interconnect structure 3, and a capacitor 4c. Unless otherwise noted, the components of the BAW device 6 shown in FIGS. 6A-6C can be structurally and/or functionally the same as or generally similar to like components of the BAW devices 1, 5 of FIGS. 1A, 1B, and 4A-4C.

The capacitor 4c can include a portion of the first electrode 10, a portion of the first passivation layer 16 in an opening 60 in the piezoelectric layer 14, and a portion of the interconnect 26 (e.g., the first conductive layer 22 and/or the second conductive layer 24) in an opening 60 in the piezoelectric layer 14. As the size of the opening 60 can at least partially contribute to the capacitance of the capacitor 4c, it can be beneficial to have a greater opening 60 to provide a greater capacitance, in some embodiments. In some embodiments, an area of the capacitor 4c that has the opening 60 can define an active area of the capacitor 4c.

As compared to the BAW device 5 of FIGS. 4A-4C, the BAW device 6 includes more piezoelectric material of the piezoelectric layer 14 in an area where the capacitor 4c is formed. For example, portions of the piezoelectric layer 14 can be disposed at two or more (e.g., all sides) of the capacitor 4c such that the portions of the first electrode 10 are covered by the portions of the piezoelectric layer 14 at two or more (e.g., all sides) of the capacitor 4c. The portions of the piezoelectric layer 14 at the sides of the capacitor 4c that cover the portions of the first electrode 10 can enable the capacitor 4c to be more robust and reliable as compared to a capacitor with less piezoelectric layer coverage.

The bulk acoustic wave devices with and the capacitors disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

FIG. 7 is a schematic diagram of an example of an acoustic wave ladder filter 120. The acoustic wave ladder filter 120 can be a transmit filter or a receive filter. The acoustic wave ladder filter 120 can be a band pass filter arranged to filter a radio frequency signal. The acoustic wave filter 120 includes series resonators S1, S2, S3, S4, and S5, shunt or parallel resonators P1, P2, P3, P4, and P5, and capacitors C1, C2, and C3 coupled between a radio frequency input/output port RF_{I/O} and an antenna port ANT. One or more of the capacitors C1, C2, and C3 can be a capacitor in accordance with any suitable principles and advantages discussed herein. The radio frequency input/output port RF_{I/O} can be a transmit port in a transmit filter or a receive port in a receive filter. An acoustic wave ladder filter can include any suitable number of series resonators, any suitable number of shunt resonators, any number of capacitors.

An acoustic wave filter can be arranged in any other suitable filter topology, such as a lattice topology or a hybrid ladder and lattice topology. A bulk acoustic wave device and a capacitor in accordance with any suitable principles and advantages disclosed herein can be implemented in a band pass filter. In some other applications, a bulk acoustic wave device and a capacitor in accordance with any suitable principles and advantages disclosed herein can be implemented in a band stop filter.

The bulk acoustic wave device and the capacitors disclosed herein can be implemented in a variety of packaged modules. Some example packaged modules will now be discussed in which any suitable principles and advantages of the bulk acoustic wave devices and the capacitors disclosed herein can be implemented. The example packaged modules can include a package that encloses the illustrated circuit elements. The illustrated circuit elements can be disposed on a common packaging substrate. The packaging substrate can be a laminate substrate, for example. Certain example packaged modules include one or more radio frequency amplifiers, such as one or more power amplifiers and/or one or more low noise amplifiers. Any suitable combination of features of these modules can be implemented with each other. While duplexers are illustrated in some examples packaged modules, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

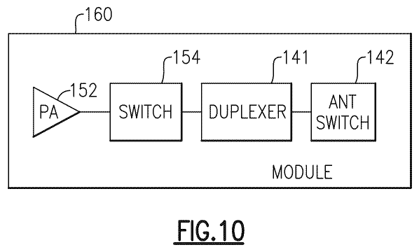

FIG. 8 is a schematic block diagram of a module 140 that includes duplexers 141A to 141N and an antenna switch 142. One or more filters of the duplexers 141A to 141N can include any suitable number of capacitors in accordance with any suitable principles and advantages discussed herein. Any suitable number of duplexers 141A to 141N can be implemented. The antenna switch 142 can have a number of throws corresponding to the number of duplexers 141A to 141N. The antenna switch 142 can electrically couple a selected duplexer to an antenna port of the module 140.

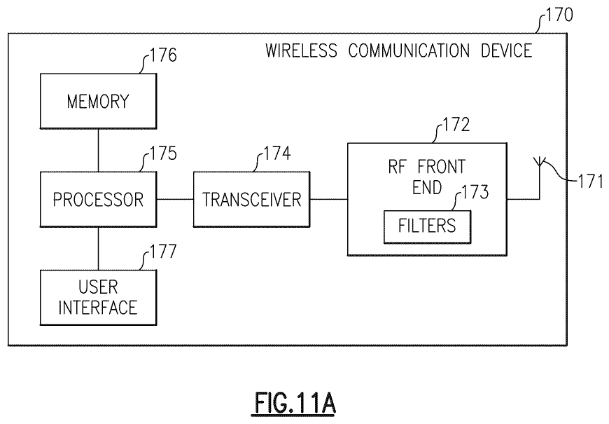

FIG. 9A is a schematic block diagram of a module 150 that includes a power amplifier 152, a radio frequency switch 154, and duplexers 141A to 141N. The power amplifier 152 can amplify a radio frequency signal. The radio frequency switch 154 can be a multi-throw radio frequency switch. The radio frequency switch 154 can electrically couple an output of the power amplifier 152 to a selected transmit filter of the duplexers 141A to 141N. One or more filters of the duplexers 141A to 141N can include any suitable number of capacitors in accordance with any suitable principles and advantages discussed herein. Any suitable number of duplexers 141A to 141N can be implemented.

FIG. 9B is a schematic block diagram of a module 155 that includes filters 156A to 156N, a radio frequency switch 157, and a low noise amplifier 158 according to an embodiment. One or more filters of the filters 156A to 156N can include any suitable number of capacitors in accordance with any suitable principles and advantages disclosed herein. Any suitable number of filters 156A to 156N can be implemented. The illustrated filters 156A to 156N are receive filters. In some embodiments (not illustrated), one or more of the filters 156A to 156N can be included in a multiplexer that also includes a transmit filter. The radio frequency switch 157 can be a multi-throw radio frequency switch. The radio frequency switch 157 can electrically couple an output of a selected filter of filters 156A to 156N to the low noise amplifier 158. In some embodiments (not illustrated), a plurality of low noise amplifiers can be implemented. The module 155 can include diversity receive features in certain applications.

FIG. 10 is a schematic block diagram of a module 160 that includes a power amplifier 152, a radio frequency switch 154, and a duplexer 141 that includes a bulk acoustic wave device with a capacitor in accordance with one or more embodiments, and an antenna switch 142. The module 160 can include elements of the module 140 and elements of the module 150.

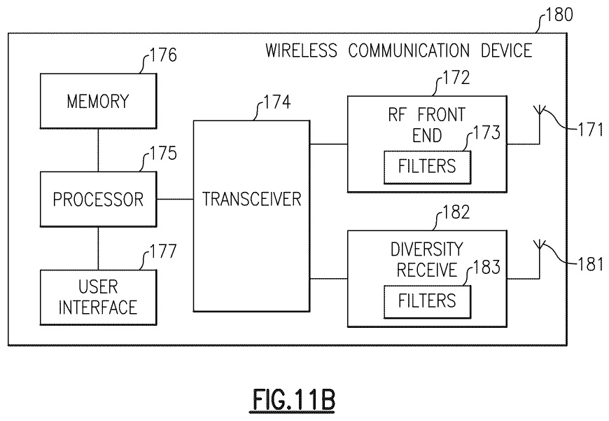

One or more filters with any suitable number of bulk acoustic devices can be implemented in a variety of wireless communication devices. FIG. 11A is a schematic block diagram of a wireless communication device 170 that includes a filter 173 with one or more bulk acoustic wave devices with a capacitor in accordance with any suitable principles and advantages disclosed herein. The wireless communication device 170 can be any suitable wireless communication device. For instance, a wireless communication device 170 can be a mobile phone, such as a smart phone. As illustrated, the wireless communication device 170 includes an antenna 171, a radio frequency (RF) front end 172 that includes filter 173, an RF transceiver 174, a processor 175, a memory 176, and a user interface 177. The antenna 171 can transmit RF signals provided by the RF front end 172. The antenna 171 can provide received RF signals to the RF front end 172 for processing.

The RF front end 172 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 172 can transmit and receive RF signals associated with any suitable communication standards. Any of the bulk acoustic wave devices with a capacitor disclosed herein can be implemented in filters 173 of the RF front end 172.

The RF transceiver 174 can provide RF signals to the RF front end 172 for amplification and/or other processing. The RF transceiver 174 can also process an RF signal provided by a low noise amplifier of the RF front end 172. The RF transceiver 174 is in communication with the processor 175. The processor 175 can be a baseband processor. The processor 175 can provide any suitable base band processing functions for the wireless communication device 170. The memory 176 can be accessed by the processor 175. The memory 176 can store any suitable data for the wireless communication device 170. The processor 175 is also in communication with the user interface 177. The user interface 177 can be any suitable user interface, such as a display.

FIG. 11B is a schematic diagram of a wireless communication device 180 that includes filters 173 in a radio frequency front end 172 and second filters 183 in a diversity receive module 182. The wireless communication device 180 is like the wireless communication device 170 of FIG. 11A, except that the wireless communication device 180 also includes diversity receive features. As illustrated in FIG. 11B, the wireless communication device 180 includes a diversity antenna 181, a diversity module 182 configured to process signals received by the diversity antenna 181 and including filters 183, and a transceiver 174 in communication with both the radio frequency front end 172 and the diversity receive module 182. One or more of the second filters 183 can include a bulk acoustic wave device with capacitor in accordance with any suitable principles and advantages disclosed herein.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can have a frequency range from 410 megahertz (MHz) to 7.125 gigahertz (GHz), for example, as specified in a current 5G NR specification. A filter arranged to filter a radio frequency signal in a 5G NR FR1 operating band can include one or more bulk acoustic wave resonators be implemented in accordance with any suitable principles and advantages disclosed herein.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

An acoustic wave filter including any suitable combination of features disclosed herein can be arranged to filter a radio frequency signal in a fifth generation (5G) New Radio (NR) operating band within Frequency Range 1 (FR1). A filter arranged to filter a radio frequency signal in a 5G NR operating band can include one or more devices of any of the stacked device arrangements disclosed herein. FR1 can be from 410 MHz to 7.125 GHz, for example, as specified in a current 5G NR specification. One or more acoustic wave filters in accordance with any suitable principles and advantages disclosed herein can be arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as semiconductor die and/or packaged radio frequency modules, electronic test equipment, uplink wireless communication devices, personal area network communication devices, etc. Examples of the consumer electronic products can include, but are not limited to, a mobile phone such as a smart phone, a wearable computing device such as a smart watch or an ear piece, a telephone, a television, a computer monitor, a computer, a router, a modem, a hand-held computer, a laptop computer, a tablet computer, a personal digital assistant (PDA), a microwave, a refrigerator, a vehicular electronics system such as an automotive electronics system, a stereo system, a DVD player, a CD player, a digital music player such as an MP3 player, a radio, a camcorder, a camera such as a digital camera, a portable memory chip, a washer, a dryer, a washer/dryer, a peripheral device, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a resonator including a first electrode, a second electrode, a piezoelectric layer between the first and second electrodes, and a passivation layer over the second electrode such that the second electrode is positioned between the piezoelectric layer and the passivation layer;
an interconnect structure including a conductive layer; and
a capacitor including the passivation layer positioned between the conductive layer and the first or second electrode in a first direction, the capacitor, the resonator, and the interconnect structure are positioned in a second direction different from the first direction.

2. The bulk acoustic wave device of claim 1 wherein the capacitor is positioned between the resonator and the interconnect structure in the second direction.

3. The bulk acoustic wave device of claim 1 wherein thicknesses of the second electrode in the resonator and the capacitor are the same.

4. The bulk acoustic wave device of claim 1 wherein the first or second electrode includes ruthenium (Ru).

5. The bulk acoustic wave device of claim 1 wherein the passivation layer in the capacitor is positioned between the conductive layer and the first electrode in the first direction, no portion of the piezoelectric layer overlaps an active region of the capacitor.

6. The bulk acoustic wave device of claim 1 wherein the passivation layer in the capacitor is positioned between the conductive layer and the second electrode in the first direction, no portion of the first electrode overlaps an active region of the capacitor.

7. The bulk acoustic wave device of claim 1 wherein the first or second electrode has a tapered edge at an edge region of the capacitor.

8. The bulk acoustic wave device of claim 1 wherein the passivation layer has a plurality of dielectric layers.

9. The bulk acoustic wave device of claim 8 wherein the plurality of dielectric layers include a silicon oxide layer and a bonding layer positioned between the second electrode and the silicon oxide layer.

10. The bulk acoustic wave device of claim 1 wherein the passivation layer in the capacitor has a thickness in a range between 200 nanometers and 400 nanometers.

11. An acoustic wave device comprising:
a bulk acoustic wave resonator including an electrode portion of a first conductive layer and a passivation portion of a dielectric layer, the electrode portion of the first conductive layer defining an electrode of the bulk acoustic wave resonator;
an interconnect structure laterally positioned relative to the bulk acoustic wave resonator, the interconnect structure including an interconnect portion of a second conductive layer; and
a capacitor laterally positioned relative to the bulk acoustic wave resonator and the interconnect structure, the capacitor including an insulator portion of the dielectric layer positioned vertically between conductor portions of the first and second conductive layers.

12. The acoustic wave device of claim 11 wherein the capacitor is positioned laterally between the bulk acoustic wave resonator and the interconnect structure.

13. The acoustic wave device of claim 11 wherein the first conductive layer includes ruthenium (Ru).

14. The acoustic wave device of claim 11 wherein the bulk acoustic wave resonator further includes a third conductive layer defining a second electrode and a piezoelectric layer positioned between the electrode and the second electrode.

15. The acoustic wave device of claim 11 wherein the passivation layer includes silicon oxide.

16. The acoustic wave device of claim 11 wherein the dielectric layer in the capacitor has a thickness in a range between 200 nanometers and 400 nanometers.

17. A capacitor in a bulk acoustic wave device, the capacitor comprising:
a first conductive layer having a material forming an electrode of a bulk acoustic wave resonator in the bulk acoustic wave device;
an insulator over the first conductive layer having a material forming a passivation layer of the bulk acoustic wave resonator; and
a second conductive layer over the insulator, the second conductive layer having a material forming a conductor of an interconnect structure in the bulk acoustic wave device.

18. The capacitor of claim 17 wherein the material of the first conductive layer is ruthenium (Ru).

19. The capacitor of claim 17 wherein the material of the insulator is silicon oxide.

20. The capacitor of claim 17 wherein the material of the second conductive layer includes gold (Au), titanium (Ti), copper (Cu), aluminum (Al), or tungsten (W).
